(19) United States
(12) Patent Application Publication
(10) Pub. No.: US 2018/0216228 A1
(43) Pub. Date: Aug. 2, 2018

(54) FABRICATION OF CORRELATED ELECTRON MATERIAL DEVICES

(71) Applicant: ARM Ltd., Cambridge (GB)

(72) Inventors: Paul Raymond Besser, Sunnyvale, CA (US); Lucian Shifren, San Jose, CA (US); Kimberly Gay Reid, Austin, TX (US); Carlos Alberto Paz de Araujo, Colorado Springs, CO (US)

(21) Appl. No.: 15/939,160

(22) Filed: Mar. 28, 2018

Related U.S. Application Data
(63) Continuation-in-part of application No. 15/046,177, filed on Feb. 17, 2016.
Application No. 15/046,177 is a continuation-in-part of application No. 15/641,124, filed on Jul. 3, 2017.
Application No. 15/641,124 is a continuation-in-part of application No. 15/385,719, filed on Dec. 20, 2016.
Application No. 15/385,719 is a continuation-in-part of application No. 15/006,889, filed on Jan. 26, 2016, now Pat. No. 9,627,615.

(51) Int. Cl. C23C 16/455; H01L 45/00

(52) U.S. Cl. CPC C23C 16/45527; H01L 45/1616; H01L 45/145

(57) ABSTRACT

Subject matter disclosed herein may relate to fabrication of correlated electron materials used, for example, to perform a switching function. In embodiments, precursors, in a gaseous form, may be utilized in a chamber to build a film of correlated electron materials comprising various impedance characteristics. In embodiments, a film of correlated electron materials may be annealed after deposition and prior to depositing a conductive material over the film.

### CROSS-REFERENCE TO RELATED APPLICATIONS

This application is a Continuation-In-Part of U.S. application Ser. No. 15/046,177, titled “FABRICATION OF CORRELATED ELECTRON MATERIAL DEVICES COMPRISING NITROGEN,” filed Feb. 17, 2016, and a Continuation-In-Part of U.S. application Ser. No. 15/641,124, titled “FABRICATING CORRELATED ELECTRON MATERIAL (CEM) DEVICES,” filed Jul. 3, 2017, and a Continuation-In-Part of U.S. application Ser. No. 15/385,719, titled “FABRICATION AND OPERATION OF CORRELATED ELECTRON MATERIAL DEVICES,” filed Dec. 20, 2016, which is a Continuation-In-Part of U.S. application Ser. No. 15/006,889, titled “FABRICATION OF CORRELATED ELECTRON MATERIAL DEVICES,” filed Jan. 26, 2016 and issued as U.S. Pat. No. 9,627,615, all of which are assigned to the assignee hereof and are expressly incorporated herein by reference in their entirety.

### BACKGROUND

### Field

Subject matter disclosed herein relates to correlated electron devices, and may relate, more particularly, to approaches toward fabricating correlated electron switching devices exhibiting desirable impedance characteristics.

### Information

Integrated circuit devices, such as electronic switching devices, for example, may be found in numerous types of electronic devices. For example, memory and/or logic devices may incorporate electronic switches suitable for use in computers, digital cameras, smart phones, computing devices, wearable electronic devices, and so forth. Factors that may relate to electronic switching devices, which may be of interest to a designer in considering whether an electronic switching device is suitable for particular applications, may include physical size, storage density, operating voltages, impedance ranges, switching speed, and/or power consumption, for example. Other factors may include, for example, cost and/or ease of manufacture, scalability, and/or reliability.

### BRIEF DESCRIPTION OF THE DRAWINGS

Claimed subject matter is particularly pointed out and distinctly claimed in the concluding portion of the specification. However, both as to organization and/or method of operation, together with objects, features, and/or advantages thereof, it may best be understood by reference to the following detailed description if read with the accompanying drawings, in which:

FIG. 1A is a diagram showing an example current density versus voltage profile of a device formed from a correlated electron material according to an embodiment;

FIG. 1B is a schematic diagram of an equivalent circuit of a correlated electron material switch according to an embodiment;

FIGS. 2A-2C are flowcharts for methods of fabricating correlated electron material films according to one or more embodiments;

FIG. 3 is a diagram of a Bis(cyclopentadienyl) molecule (Ni(C₅H₅)₂), which may function as an example precursor, in a gaseous form, utilized in fabrication of correlated electron material devices according to an embodiment;

FIGS. 4A-4D show sub-processes utilized in a method for fabricating correlated electron material devices according to an embodiment;

FIGS. 5A-5D are diagrams showing gas flow and temperature profiles, as a function of time, which may be used in a method for fabricating correlated electron material devices according to an embodiment;

FIGS. 5E-5H are diagrams showing precursor flow and temperature profiles, as a function of time, which may be used in a method for fabricating correlated electron device materials according to an embodiment;

FIGS. 6A-6C are diagrams showing temperature profiles, as a function of time, used in deposition and annealing processes for fabricating correlated electron material devices according to an embodiment; and

FIGS. 7 and 8 are flowcharts for additional methods of fabricating correlated electron material films according to one or more embodiments.

Reference is made in the following detailed description to accompanying drawings, which form a part hereof, wherein like numerals may designate like parts throughout that are corresponding and/or analogous. It will be appreciated that the figures have not necessarily been drawn to scale, such as for simplicity and/or clarity of illustration. For example, dimensions of some aspects may be exaggerated relative to others. Further, it is to be understood that other embodiments may be utilized. Furthermore, structural and/or other changes may be made without departing from claimed subject matter. References throughout this specification to “claimed subject matter” refer to subject matter intended to be covered by one or more claims, or any portion thereof, and are not necessarily intended to refer to a complete claim set, to a particular combination of claim sets (e.g., method claims, apparatus claims, etc.), or to a particular claim. It should also be noted that directions and/or references, for example, such as up, down, top, bottom, and so on, may be used to facilitate discussion of drawings and are not intended to restrict application of claimed subject matter. Therefore, the following detailed description is not to be taken to limit claimed subject matter and/or equivalents.

### DETAILED DESCRIPTION

References throughout this specification to one implementation, an implementation, one embodiment, an embodiment, and/or the like means that a particular feature, structure, characteristic, and/or the like described in relation to a particular implementation and/or embodiment is included in at least one implementation and/or embodiment of claimed subject matter. Thus, appearances of such phrases, for example, in various places throughout this specification are not necessarily intended to refer to the same implementation and/or embodiment or to any one particular implementation and/or embodiment. Furthermore, it is to be understood that particular features, structures, characteristics, and/or the like described are capable of being combined in various ways in one or more implementations and/or embodiments and, therefore, are within intended claim scope. In general, of course, as has been the case for the specification of a patent application, these and other issues have a potential to vary in a particular context of usage. In other words, throughout the disclosure, particular context of description and/or usage provides helpful guidance regarding reasonable inferences to be drawn; however, likewise, “in this context” in general without further qualification refers to the context of the present disclosure.

Particular aspects of the present disclosure describe methods and/or processes for preparing and/or fabricating correlated electron materials (CEMs) films to form, for example, CEM switches, such as may be utilized to form a correlated electron random access memory (CERAM), and/or logic devices, for example. CEMs, which may be utilized in the construction of CERAM devices and CEM switches, for example, may also comprise a wide range of other electronic circuit types, such as, for example, memory controllers, memory arrays, filter circuits, data converters, optical instruments, phase locked loop circuits, microwave and millimeter wave transceivers, and so forth, although claimed subject matter is not limited in scope in these respects.

In this context, a CEM switch, for example, may exhibit a substantially rapid conductor-to-insulator transition, which may be enabled, at least in part, by electron correlations rather than solid state structural phase changes, such as in response to a change from a crystalline to an amorphous state, for example, in a phase change memory device or, in another example, formation of filaments in certain resistive RAM devices. In one aspect, a substantially rapid conductor-to-insulator transition in a CEM device may be responsive to a quantum mechanical phenomenon, in contrast to melting/solidification or filament formation, for example, in phase change and certain resistive RAM devices. Such quantum mechanical transitions between relatively conductive and relatively insulative states, and/or between a first impedance state and a second, dissimilar impedance state, for example, in a CEM device may be understood in any one of several aspects. As used herein, the terms “relatively conductive state,” “relatively lower impedance state,” and/or “metal state” may be interchangeable, and/or may, at times, be referred to as a “relatively conductive/lower impedance state.” Likewise, the terms “relatively insulative state” and “relatively higher impedance state” may be used interchangeably herein, and/or may, at times, be referred to as a “relatively insulative/higher impedance state.”

In an aspect, a quantum mechanical transition of a CEM between a relatively insulative/higher impedance state and a relatively conductive/lower impedance state, wherein the relatively conductive/lower impedance state is substantially dissimilar from the insulated/higher impedance state, may be understood in terms of a Mott transition. In accordance with a Mott transition, a material may switch between a relatively insulative/higher impedance state and a relatively conductive/lower impedance state if a Mott transition condition occurs. The Mott criteria may be defined by (n_{c})^{1/3}a≈0.26, wherein n_{c} denotes a concentration of electrons, and wherein “a” denotes the Bohr radius. If a threshold carrier concentration is achieved, such that the Mott criteria is met, the Mott transition is believed to occur. Responsive to the Mott transition occurring, the state of the CEM device changes from a relatively higher resistance/higher capacitance state (e.g., an insulative/higher impedance state) to a relatively lower resistance/lower capacitance state (e.g., a conductive/lower impedance state) that is substantially dissimilar from the higher resistance/higher capacitance state.

In another aspect, a Mott transition may be controlled by a localization of electrons. If carriers, such as electrons, for example, are localized, a strong coulomb interaction between the carriers may split the bands of the CEM to enable a relatively insulative (relatively higher impedance) state. If electrons are no longer localized, a weak coulomb interaction may dominate, which may give rise to a removal of band splitting, which may, in turn, enable a metal (conductive) band (relatively lower impedance state) that is substantially dissimilar from the relatively higher impedance state.

Further, in an embodiment, switching from a relatively insulative/higher impedance state to a substantially dissimilar and relatively conductive/lower impedance state may enable a change in capacitance in addition to a change in resistance. For example, a CEM device may exhibit a variable resistance together with a property of variable capacitance. In other words, impedance characteristics of a CEM device may include both resistive and capacitive components. For example, in a metal state, a CEM device may comprise a relatively low electric field that may approach zero, and therefore may exhibit a substantially low capacitance, which may likewise approach zero.

Similarly, in a relatively insulative/higher impedance state, which may be brought about by a higher density of bound or correlated electrons, an external electric field may be capable of penetrating the CEM and, therefore, the CEM may exhibit higher capacitance based, at least in part, on additional charges stored within the CEM. Thus, for example, a transition from a relatively insulative/higher impedance state to a substantially dissimilar and relatively conductive/lower impedance state in a CEM device may result in changes in both resistance and capacitance, at least in particular embodiments. Such a transition may give rise to additional measurable phenomena, and claimed subject matter is not limited in this respect.

In an embodiment, a device formed from a CEM may exhibit switching of impedance states responsive to a Mott-transition in a portion, such as a major portion, of the volume of a CEM-based device. In an embodiment, a CEM may form a “bulk switch.” As used herein, the term “bulk switch” refers to at least a majority volume of a CEM switching an impedance state of the device, such as in response to a Mott-transition. For example, in an embodiment, substantially all CEM of a device may switch between a relatively insulative/higher impedance state and a relatively conductive/lower impedance state (e.g., a “metal” or “metallic state”) responsive to a Mott transition, or from a relatively conductive/lower impedance state to a relatively insulative/higher impedance state responsive to a reverse Mott transition.

In implementations, a CEM may comprise one or more “d-block” elements or compounds of “d-block” elements. The CEM may, for example, comprise one or more transition metals or transition metal compounds, and, in particular, one or more transition metal oxides (TMOs). CEM devices may also be implemented utilizing one or more “f-block” elements or compounds of “f-block” elements. A CEM may comprise one or more rare earth elements, oxides of rare earth elements, oxides comprising one or more rare earth transition metals, perovskites, yttrium, and/or ytterbium, or any other compounds comprising metals from the lanthanide or actinide series of the periodic table of the elements, for example, and claimed subject matter is not limited in scope in this respect. A CEM may additionally comprise a dopant, such as a carbon-containing dopant and/or a nitrogen-containing dopant, wherein the atomic concentration (e.g., of carbon or nitrogen) comprise between about 0.1% to about 15.0%. As the term is used herein, a “d-block” element means an element comprising scandium (Sc), titanium (Ti), vanadium (V), chromium (Cr), manganese (Mn), iron (Fe), cobalt (Co), nickel (Ni), copper (Cu), zinc (Zn), yttrium (Y), zirconium (Zr), niobium (Nb), molybdenum (Mo), technetium (Tc), ruthenium (Ru), rhodium (Rh), palladium (Pd), silver (Ag), cadmium (Cd), hafnium (Hf), tantalum (Ta), tungsten (W), rhenium (Re), osmium (Os), iridium (Ir), platinum (Pt), gold (Au), mercury (Hg), rutherfordium (RI), dubnium (Db), seaborgium (Sg), bohrium (Bh), hassium (Hs), meitnerium (Mt), darmstadtium (Ds), roentgenium (Rg) or copernicium (Cn), or any combination thereof. A CEM formed from or comprising an “f-block” element of the periodic table of the elements means a CEM comprising a metal or metal oxide, wherein the metal is from the f-block of the periodic table of the elements, which may include lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), lutetium (Lu), actinium (Ac), thorium (Th), protactinium (Pa), uranium (U), neptunium (Np), plutonium (Pu), americium (Am), berkelium (Bk), californium (Cf), einsteinium (Es), fermium (Fm), mendelevium (Md), nobelium (No) or lawrencium (Lr), or any combination thereof.

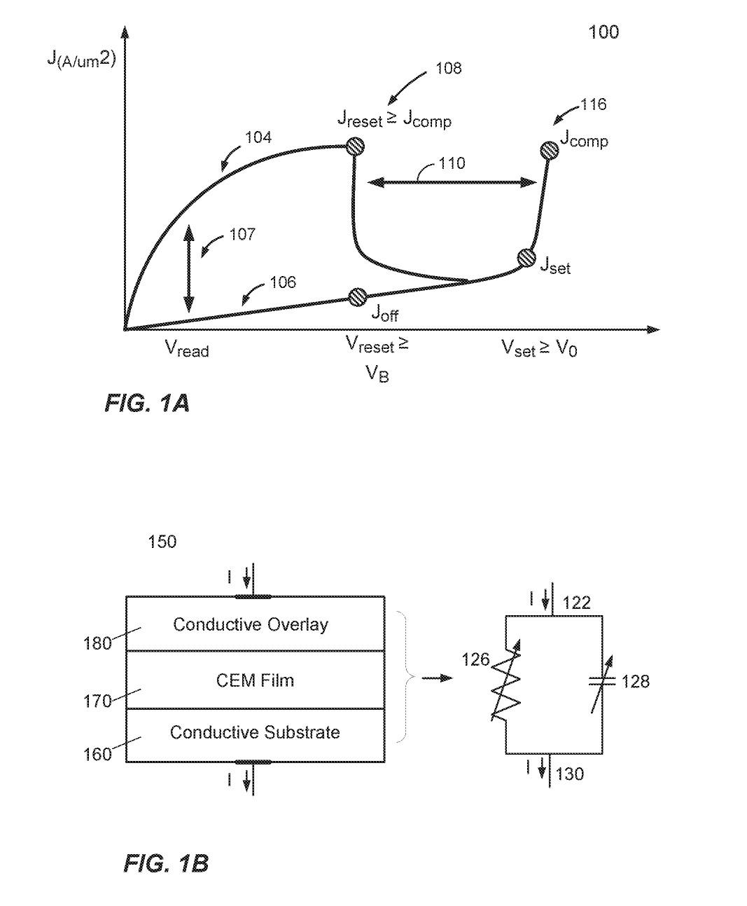

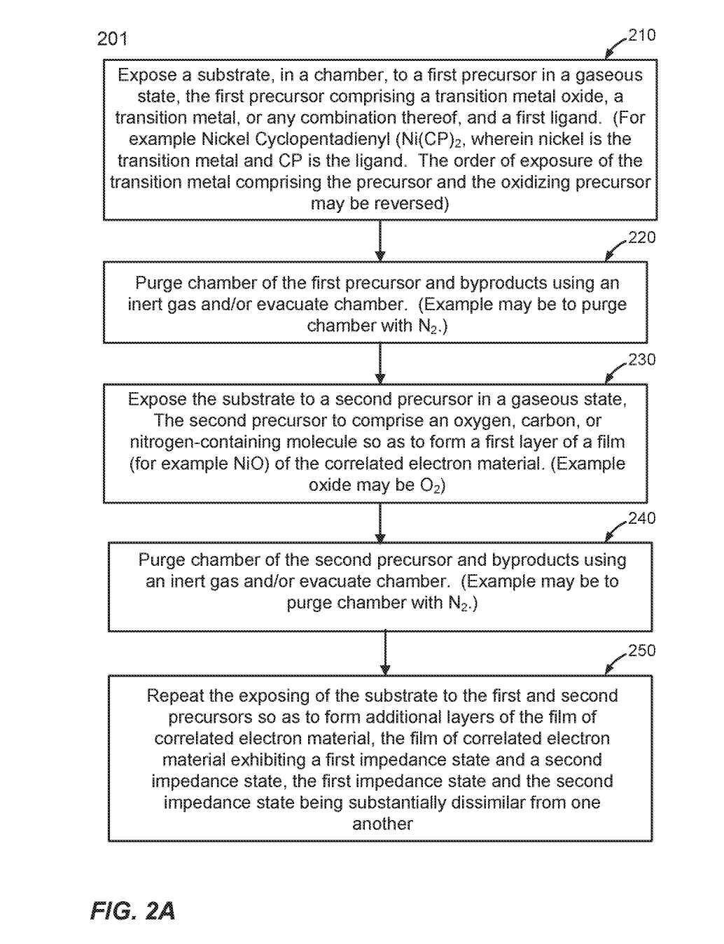

FIG. 1A is an illustration of an embodiment 100 of a current density versus voltage profile of a device formed from a correlated electron material. Based, at least in part, on a voltage applied to terminals of a CEM device, for example, during a “write operation,” the CEM device may be placed into a relatively low-impedance state or a relatively high-impedance state. For example, application of a voltage Vₛₑₜ and a current density Jₛₑₜ may enable a transition of the CEM device to a relatively low-impedance state. Conversely, application of a voltage Vᵣₑₛₑₜ and a current density Jᵣₑₛₑₜ may enable a transition of the CEM device to a relatively high-impedance state. As shown in FIG. 1A, reference designator 110 illustrates the voltage range that may separate Vₛₑₜ from Vᵣₑₛₑₜ. Following placement of the CEM device into a high-impedance state or into a low-impedance state, the particular state of the CEM device may be detected by application of a voltage V_{read} (e.g., during a read operation) and detection of a current or current density at terminals of the CEM device (e.g., utilizing read window 107).

According to an embodiment, the CEM device characterized in FIG. 1A may comprise any transition metal oxide (TMO), such as, for example, perovskites, Mott insulators, charge exchange insulators, and Anderson disorder insulators, as well as any compound or material comprising a d-block or f-block element. In one aspect, the CEM device of FIG. 1A may comprise other types of TMO variable impedance materials, though it should be understood that these are exemplary only and are not intended to limit claimed subject matter. Nickel oxide (NiO) is disclosed as one particular TMO material. NiO materials discussed herein may be doped with extrinsic ligands, such as carbon-containing materials (e.g., carbonyl (CO)), or nitrogen-containing materials, such as ammonia (NH₃), for example, which may establish and/or stabilize variable impedance properties and/or enable a P-type operation in which a CEM may be more conductive when placed into a low-impedance state. Thus, in another particular example, NiO doped with extrinsic ligands may be expressed as NiO:Lₓ, where Lₓ may indicate a ligand element or compound and x may indicate a number of units of the ligand for one unit of NiO. A value of x may be determined for any specific ligand and any specific combination of ligand with NiO or with any other transition metal compound simply by balancing valences. Other dopant ligands, which may enable or increase conductivity in a low-impedance state in addition to carbonyl may include: nitrosyl (NO), an isocyanide (RNC wherein R is H, C₁-C₆ alkyl or C₆-C₁₀ aryl), a phosphine (R₃P wherein R is C₁-C₆ alkyl or C₆-C₁₀ aryl) for example, triphenylphosphine (PPh₃), an alkyne (e.g. ethyne) or phenanthroline (C₁₂H₈N₂), bipyridine (C₁₀H₈N₂), ethylenediamine (C₂H₄(NH₂)₂), acetonitrile (CH₃CN), fluoride (F), chloride (Cl), bromide (Br), cyanide (CN), sulfur (S), carbon (C), and others.

In this context, a “P-type” doped CEM as referred to herein means a first type of CEM comprising a particular molecular dopant that exhibits increased electrical conductivity, relative to an undoped CEM, when the CEM is operated in a relatively low-impedance state. Introduction of a substitutional ligand, such as CO and NH₃, may operate to enhance the P-type nature of a NiO-based CEM, for example. Accordingly, an attribute of P-type operation of a CEM may include, at least in particular embodiments, an ability to tailor or customize electrical conductivity of a CEM, operated in a relatively low-impedance state, by controlling an atomic concentration of a P-type dopant in a CEM. In particular embodiments, an increased atomic concentration of a P-type dopant may enable increased electrical conductivity of a CEM, although claimed subject matter is not limited in this respect. In particular embodiments, changes in atomic concentration of P-type dopant in a CEM device may be observed in the characteristics of region 104 of FIG. 1A, as described herein, wherein an increase in P-type dopant brings about a steeper (e.g., more positive) slope of region 104 to indicate higher conductivity.

In another embodiment, the CEM device represented by the current density versus voltage profile of FIG. 1A, may comprise other TMO variable impedance materials, such as nitrogen-containing ligands, though it should be understood that these are exemplary only and are not intended to limit claimed subject matter. NiO, for example, may be doped with substitutional nitrogen-containing ligands, which may stabilize variable impedance properties in a manner similar to stabilization of variable impedance properties brought about by use of carbon or a carbon-containing dopant species (e.g., carbonyl). In particular, NiO variable impedance materials disclosed herein may include nitrogen-containing molecules of the form CₓH_{y}N_{z} (wherein x≥0, y≥0, z≥0, and wherein at least x, y, or z comprise values>0) such as: ammonia (NH₃), cyano (CN⁻), azide ion (N₃⁻) ethylene diamine (C₂H₈N₂), phen(1,10-phenanthroline) (C₁₂H₈N₂), 2,2′bipyridine (C₁₀,H₈N₂), ethylenediamine ((C₂H₄(NH₂)₂), pyridine (C₅H₅N), acetonitrile (CH₃CN), and cyanosulfanides such as thiocyanate (NCS⁻), for example. NiO variable impedance materials disclosed herein may include members of an oxynitride family (NₓO_{y}, wherein x and y comprise whole numbers, and wherein x≥0 and y≥0 and at least x or y comprise values>0), which may include, for example, nitric oxide (NO), nitrous oxide (N₂O), nitrogen dioxide (NO₂), or precursors with an NO₃⁻ ligand.

In accordance with FIG. 1A, if a sufficient bias voltage is applied (e.g., exceeding a band-splitting potential) and the aforementioned Mott condition is satisfied (e.g., injected electron holes are of a population comparable to a population of electrons in a switching region, for example), a CEM device may switch between a relatively low-impedance state and a relatively high-impedance state, for example, responsive to a Mott transition. This may correspond to point 108 (Vᵣₑₛₑₜ) of the voltage versus current density profile of FIG. 1A. At, or suitably near this point, electrons are no longer screened and become localized near the metal ion. This correlation may result in a strong electron-to-electron interaction potential, which may operate to split the bands to form a relatively high-impedance material. If the CEM device comprises a relatively high-impedance state, current may be generated by transportation of electron holes. Consequently, if a threshold voltage is applied across terminals of the CEM device, electrons may be injected into a metal-insulator-metal (MIM) diode over the potential barrier of the MIM device. In certain embodiments, injection of a threshold current of electrons, at a threshold potential applied across terminals of a CEM device, may perform a “set” operation, which places the CEM device into a low-impedance state. In a low-impedance state, an increase in electrons may screen incoming electrons and remove a localization of electrons, which may operate to collapse the band-splitting potential, thereby giving rise to the low-impedance state.

According to an embodiment, current in a CEM device may be controlled by an externally applied “compliance” condition, which may be determined at least partially on the basis of an applied external current, which may be limited during a write operation, for example, to place the CEM device into a relatively high-impedance state. This externally applied compliance current may, in some embodiments, also set a condition of a current density for a subsequent reset operation to place the CEM device into a relatively high-impedance state. As shown in the particular implementation of FIG. 1A, a voltage Vₛₑₜ may be applied during a write operation to give rise to a current density J_{comp}, such as at point 116, to place the CEM device into a relatively low-impedance state, which may determine a compliance condition for placing the CEM device into a relatively high-impedance state in a subsequent write operation. As shown in FIG. 1A, a CEM device may be subsequently placed into a relatively high-impedance state by application of an externally applied voltage (Vᵣₑₛₑₜ), which may give rise to a current density Jᵣₑₛₑₜ≥J_{comp} at a voltage referenced by 108 in FIG. 1A.

In embodiments, compliance may set a number of electrons in a CEM device that may be “captured” by holes for the Mott transition. In other words, a current applied in a write operation to place a CEM device into a relatively low-impedance state may determine a number of holes to be injected to the CEM device for subsequently transitioning the CEM device to a relatively high-impedance state.

As pointed out above, a reset condition may occur in response to a Mott transition at point 108. As pointed out above, such a Mott transition may give rise to a condition in a CEM device in which a concentration of electrons n approximately equals, or becomes at least comparable to, a concentration of electron holes p. This condition may be modeled according to expression (1) as follows:

$${λ}_{TF} {n}^{\frac{1}{3}} = C ∼ 0.26 \\ n = {( \frac{C}{{λ}_{TF}} )}^{3} \qquad ( 1 )$$

In expression (1), λ_{TF} corresponds to a Thomas Fermi screening length, and C is a constant.

According to an embodiment, a current or current density in region 104 of the voltage versus current density profile shown in FIG. 1A, may exist in response to injection of holes from a voltage signal applied across terminals of a CEM device, which may correspond to P-type operation of the CEM device. Here, injection of holes may meet a Mott criterion for the low-impedance state to high-impedance state transition at current I_{MI} as a threshold voltage V_{MI} is applied across terminals of a CEM device. This may be modeled according to expression (2) as follows:

$${I}_{MI} ( {V}_{MI} ) = \frac{dQ ( {V}_{MI} )}{dt} \approx \frac{Q ( {V}_{MI} )}{t} \\ Q ( {V}_{MI} ) = qn ( {V}_{MI} ) \qquad ( 2 )$$

In expression (2), Q(V_{MI}) corresponds to the charged injected (holes or electrons) and is a function of an applied voltage. Injection of electrons and/or holes to enable a Mott transition may occur between bands and in response to threshold voltage V_{MI}, and threshold current I_{MI}. By equating electron concentration n with a charge concentration to give rise to a Mott transition by holes injected by I_{MI} in expression (2) according to expression (1), a dependency of such a threshold voltage V_{MI} on Thomas Fermi screening length λ_{TF} may be modeled substantially in accordance with expression (3), as follows:

$${I}_{MI} ( {V}_{MI} ) = \frac{Q ( {V}_{MI} )}{t} = \frac{qn ( {V}_{MI} )}{t} = \frac{q}{t} {( \frac{C}{{λ}_{TF}} )}^{3} \\ {J}_{reset} ( {V}_{MI} ) = {J}_{MI} ( {V}_{MI} ) = \frac{{I}_{MI} ( {V}_{MI} )}{{A}_{CEM}} = \frac{q}{{A}_{CEM} t} {( \frac{C}{{λ}_{TF}} )}^{3} \qquad ( 3 )$$

In expression (3), A_{CEM} corresponds to a cross-sectional area of a CEM device; and Jᵣₑₛₑₜ(V_{MI}) may represent a current density through the CEM device to be applied to the CEM device at a threshold voltage V_{MI}, which may place the CEM device into a relatively high-impedance state.

According to an embodiment, a CEM device, which may be utilized to form a CEM switch, a CERAM memory device, or a variety of other electronic devices comprising one or more correlated electron materials, may be placed into a relatively low-impedance state, such as by transitioning from a relatively high-impedance state, for example, via injection of a sufficient quantity of electrons to satisfy a Mott criteria. In transitioning a CEM device to a relatively low-impedance state, if enough electrons are injected and the potential across the terminals of the CEM device overcomes a threshold switching potential (e.g., Vₛₑₜ), injected electrons may begin to screen. As previously mentioned, screening may operate to unlocalize double-occupied electrons to collapse the band-splitting potential, thereby bringing about a relatively low-impedance state.

In particular embodiments, changes in impedance states of CEM devices, such as changes from a low-impedance state to a substantially dissimilar high-impedance state, for example, may be brought about by “back-donation” of electrons of compounds comprising NiₓO_{y} (wherein the subscripts “x” and “y” comprise whole numbers). As the term is used herein, “back-donation” refers to a supplying of one or more electrons (e.g., increased electron density) to a transition metal, transition metal oxide, or any combination thereof (e.g., to an atomic orbital of a metal), by an adjacent molecule of a lattice structure, such as a ligand or dopant. Back-donation also refers to reversible donation of electrons (e.g., an increase electron density) from a metal atom to an unoccupied π-antibonding orbital on a ligand or dopant. Back-donation may permit a transition metal, transition metal compound, transition metal oxide, or a combination thereof, to maintain an ionization state that is favorable to electrical conduction under an influence of an applied voltage. In certain embodiments, back-donation in a CEM, for example, may occur responsive to use of carbon (C), carbonyl (CO), or a nitrogen-containing dopant species, such as ammonia (NH₃), ethylene diamine (C₂H₈N₂), or members of an oxynitride family (NₓO_{y}), for example, which may permit a CEM to exhibit a property in which electrons are controllably, and reversibly, “donated” to a conduction band of the transition metal or transition metal oxide, such as nickel, for example, during operation of a device or circuit comprising a CEM. Back donation may be reversed, for example, in a nickel oxide material (e.g., NiO:CO or NiO:NH₃), thereby permitting the nickel oxide material to switch to exhibiting a substantially dissimilar impedance property, such as a high-impedance property, during device operation.

Thus, in this context, an electron back-donating dopant refers to a material that enables a TMO material film to exhibit an impedance switching property, such as switching from a first impedance state to a substantially dissimilar second impedance state (e.g., from a relatively low impedance state to a relatively high impedance state, or vice versa) based, at least in part, on influence of an applied voltage to control donation of electrons, and reversal of the electron donation, to and from a conduction band of the CEM.

In some embodiments, by way of back-donation, a CEM switch comprising a transition metal, transition metal compound, or transition metal oxide, may exhibit low-impedance properties if the transition metal, such as nickel, for example, is placed into an oxidation state of 2+(e.g., Ni²⁺ in a material, such as NiO:CO or NiO:NH₃). Conversely, electron back-donation may be reversed if a transition metal, such as nickel, for example, is placed into an oxidation state of 1+ or 3+. Accordingly, during operation of a CEM device, back-donation may result in “disproportionation,” which may comprise substantially simultaneous oxidation and reduction reactions, substantially in accordance with expression (4), below:

2Ni²⁺→Ni¹⁺+Ni³⁺ (4)

Such disproportionation, in this instance, refers to formation of nickel ions as Ni¹⁺+Ni³⁺ as shown in expression (4), which may bring about, for example, a relatively high-impedance state during operation of the CEM device. In an embodiment, a dopant such as carbon or a carbon-containing ligand (e.g., carbonyl (CO)) or a nitrogen-containing ligand, such as an ammonia molecule (NH₃), may permit sharing of electrons during operation of a CEM device to give rise to the disproportionation reaction of expression (4), and its reversal, substantially in accordance with expression (5), below:

Ni¹⁺+Ni³⁺→2Ni²⁺ (5)

As previously mentioned, reversal of the disproportionation reaction, as shown in expression (5), permits a nickel-based CEM to return to a relatively low-impedance state.

In embodiments, depending on a molecular concentration of NiO:CO or NiO:NH₃, for example, which may vary from values approximately in the range of an atomic concentration of 0.1% to 15.0%, Vᵣₑₛₑₜ and Vₛₑₜ, as shown in FIG. 1A, may vary from about 1.0 V to about 10.0 V, subject to the condition that Vₛₑₜ≥Vᵣₑₛₑₜ. For example, in one possible embodiment, Vᵣₑₛₑₜ may occur at a voltage approximately in the range of 0.1 V to 1.0 V, and Vₛₑₜ may occur at a voltage approximately in the range of 1.0 V to 2.0 V, for example. It should be noted, however, that variations in Vₛₑₜ and Vᵣₑₛₑₜ may occur based, at least in part, on a variety of factors, such as atomic concentration of an electron back-donating material, such as NiO:CO or NiO:NH₃ and other materials present in the CEM device, as well as variations in processes utilized to fabricate CEM devices, and claimed subject matter is not limited in this respect.

FIG. 1B is an illustration of an embodiment 150 of a switching device comprising a correlated electron material and a schematic diagram of an equivalent circuit of a correlated electron material switch. As previously mentioned, a correlated electron device, such as a CEM switch, a CERAM array, or other type of device utilizing one or more correlated electron materials may comprise a variable or complex impedance device that may exhibit characteristics of both variable resistance and variable capacitance. In other words, impedance characteristics for a CEM variable impedance device, such as a device comprising a conductive substrate 160, CEM film 170, and conductive overlay 180, may depend, at least in part, on resistance and capacitance characteristics of the device measured across device terminals 122 and 130. In an embodiment, an equivalent circuit for a variable impedance device may comprise a variable resistor, such as variable resistor 126, in parallel with a variable capacitor, such as variable capacitor 128. Of course, although variable resistor 126 and variable capacitor 128 are depicted in FIG. 1B as comprising discrete components, a variable impedance device, such as the device of embodiment 150, may comprise a substantially homogenous CEM film and claimed subject matter is not limited in this respect.

Table 1 below depicts an example truth table for an example variable impedance device, such as the device of embodiment 150.

TABLE 1
Correlated Electron Switch Truth Table

| Resistance | Capacitance | Impedance |
|---|---|---|
| R_{high}(V_{applied}) | C_{high}(V_{applied}) | Z_{high}(V_{applied}) |
| R_{low}(V_{applied}) | C_{low}(V_{applied})~0 | Z_{low}(V_{applied}) |

Table 1 shows that a resistance of a variable impedance device, such as the device of embodiment 150, may transition between a low-impedance state and a substantially dissimilar, high-impedance state as a function at least partially dependent on a voltage applied across a CEM device. In an embodiment, an impedance exhibited at a low-impedance state may be approximately in the range of 10.0-100,000.0 times lower than an impedance exhibited in a high-impedance state. In other embodiments, an impedance exhibited at a low-impedance state may be approximately in the range of 5.0 to 10.0 times lower than an impedance exhibited in a high-impedance state, for example. It should be noted, however, that claimed subject matter is not limited to any particular impedance ratios between relatively high-impedance states and relatively low-impedance states. Table 1 shows that a capacitance of a variable impedance device, such as the device of embodiment 150, may transition between a lower capacitance state, which, in an example embodiment, may comprise approximately zero (or very little) capacitance, and a higher capacitance state that is based, at least in part, on a voltage applied across a CEM device.

In certain embodiments, atomic layer deposition may be utilized to form or to fabricate films comprising NiO materials, such as NiO:CO or NiO:NH₃. In this context, a “layer,” as the term is used herein, means a sheet or coating of material, which may be disposed on or over an underlying formation, such as a conductive or insulating substrate. For example, a layer deposited on an underlying substrate by way of an atomic layer deposition process may comprise a thickness of a single atom, which may comprise a thickness of a fraction of an angstrom (e.g., 0.6 Å). However, a layer encompasses a sheet or coating having a thickness greater than that of a single atom depending, for example, on a process utilized to fabricate CEM films formed from TMO materials. Additionally, a “layer” may be oriented horizontally (e.g. a “horizontal” layer), oriented vertically (e.g., a “vertical” layer), or may be positioned in any other orientation, such as diagonally, for example. In embodiments, a CEM film may comprise a sufficient number of layers, to permit electron back-donation during operation of a CEM device in a circuit environment, for example, to give rise to a low-impedance state. Also during operation in a circuit environment, for example, electron back-donation may be reversed to give rise to a substantially dissimilar impedance state, such as a high-impedance state, for example.

Also in this context, a “substrate” as used herein means a structure comprising a surface that enables materials, such as materials having particular electrical properties (e.g., conductive properties, insulative properties, etc.) to be deposited or placed on or over the substrate. For example, in a CEM-based device, a conductive substrate, such as conductive substrate 160, for example, may operate to convey an electrical current to a CEM film in contact with conductive substrate 160. In another example, a substrate may operate to insulate a CEM film to substantially reduce or to prohibit electrical current flow to or from the CEM film. In one possible example of an insulating substrate, a material such as silicon nitride (SiN) may be employed to insulate components of semiconductor structures. Further, an insulating substrate may comprise other silicon-based materials, such as silicon-on-insulator or silicon-on-sapphire technology, doped and/or undoped semiconductors, epitaxial layers of silicon supported by a base semiconductor foundation, conventional metal oxide semiconductors (e.g., a CMOS front end with a metal back end) and/or other semiconductor structures and/or technologies, including CEM switching devices. Accordingly, claimed subject matter is intended to embrace a wide variety of conductive and insulating substrates without limitation.

In particular embodiments, formation of CEM films from TMO materials on or over a substrate may utilize two or more precursors to deposit components of, for example, NiO:CO or NiO:NH₃, or other TMO, transition metal, or combination thereof, onto a conductive material such as a substrate. In an embodiment, layers of a TMO material film may be deposited utilizing separate precursor molecules, AX and BY, according to expression (6a), below:

AX_{(gas)}+BY_{(gas)}=AB_{(solid)}+XY_{(gas)} (6a)

Wherein “A” of expression (6a) corresponds to a transition metal, transition metal compound, transition metal oxide, or any combination thereof. In embodiments, a transition metal oxide may comprise nickel, but may comprise other transition metals, transition metal compounds, and/or transition metal oxides, such as aluminum, cadmium, chromium, cobalt, copper, gold, iron, manganese, mercury, molybdenum, nickel palladium, rhenium, ruthenium, silver, tantalum, tin, titanium, vanadium, yttrium, or zinc (which may be linked to an anion, such as oxygen or other types of ligands), or combinations thereof, although claimed subject matter is not limited in scope in this respect. In particular embodiments, compounds that comprise more than one transition metal oxide may also be utilized, such as yttrium titanate (YTiO₃).

In embodiments, “X” of expression (6a) may comprise one or more of a ligand, such as an organic ligand, including amidinate (AMD), di(cyclopentadienyl) (Cp)₂, di(ethylcyclopentadienyl) (EtCp)₂, bis(2,2,6,6-tetramethylheptane-3,5-dionato) ((thd)₂), acetylacetonate (acac), bis(methylcyclopentadienyl) ((CH₃C₅H₄)₂), dimethylglyoximate (dmg), 2-amino-pent-2-en-4-onato (apo), (dmamb)₂ where dmamb_=_1-dimethylamino-2-methyl-2-butanolate, (dmamp)₂ where dmamp_=_1-dimethylamino-2-methyl-2-propanolate, di(pentamethylcyclopentadienyl) (C₅(CH₃)₅)₂ and carbonyl (CO)₄. Accordingly, in some embodiments, nickel-based precursor AX may comprise, for example, nickel amidinate (Ni(AMD)), bis(cyclopentadienyl)nickel (Ni(Cp)₂), bis(ethylcyclopentadienyl)nickel (Ni(EtCp)₂), bis(2,2,6,6-tetramethylheptane-3,5-dionato)Ni(II) (Ni(thd)₂), nickel acetylacetonate (Ni(acac)₂), bis(methylcyclopentadienyl)nickel (Ni(CH₃C₅H4)₂, nickel dimethylglyoximate (Ni(dmg)₂), nickel 2-amino-pent-2-en-4-onato (Ni(apo)₂), Ni(dmamb)₂ where dmamb=1-dimethylamino-2-methyl-2-butanolate, Ni(dmamp)₂ where dmamp=1-dimethylamino-2-methyl-2-propanolate, bis(pentamethylcyclopentadienyl)nickel (Ni(C₅(CH₃)₅)₂, and nickel tetracarbonyl (Ni(CO)₄), just to name a few examples.

However, in particular embodiments, a dopant operating as an electron back-donating species in addition to precursors AX and BY may be utilized to form layers of a TMO film. An electron back-donating species, which may co-flow with precursor AX, may permit formation of electron back-donating compounds, substantially in accordance with expression (6b), below. In embodiments, a dopant species or a precursor to a dopant species, such as carbon (C), ammonia (NH₃), methane (CH₄), carbon monoxide (CO), or other precursors and/or dopant species may be utilized, may provide electron back-donating ligands listed above. Thus, expression (6a) may be modified to include an additional dopant ligand substantially in accordance with expression (6b), below:

$${AX}_{( gas )} + ( {NH}_{3} or other ligand comprising nitrogen ) + {BY}_{( gas )} = AB \text{:} {NH}_{3 ( solid )} + {XY}_{( gas )} \qquad ( 6 b )$$

It should be noted that concentrations, such as atomic concentrations, of precursors, such as AX, BY, and NH₃ (or other ligand comprising nitrogen) of expressions (6a) and (6b) may be adjusted to give rise to a final atomic concentration of nitrogen-containing or carbon-containing dopant to permit electron back-donation in a fabricated CEM device. As referred to herein, the term “atomic concentration” means the concentration of atoms in the finished material that derive from the substitutional ligand. For example, in the case in which the substitutional ligand is CO, the atomic concentration of CO comprises the total number of carbon atoms that comprise the material film divided by the total number of atoms in the material film, multiplied by 100.0. In another example, for the case in which the substitutional ligand is NH₃, the atomic concentration of NH₃ comprises the total number of nitrogen atoms that comprise the material film divided by the total number of atoms in the material film, multiplied by 100.0.

In particular embodiments, nitrogen or carbon containing dopants may comprise ammonia (NH₃), carbon (C), or carbonyl (CO) in an atomic concentration of between about 0.1% and 15.0%. In particular embodiments, atomic concentrations of dopants, such as NH₃ and CO, may comprise a more limited range of atomic concentrations such as, for example, between about 1.0% and 10.0%. However, claimed subject matter is not necessarily limited to the above-identified precursors and/or atomic concentrations. It should be noted that, claimed subject matter is intended to embrace all such precursors and atomic concentrations of dopants utilized in atomic layer deposition, chemical vapor deposition, plasma chemical vapor deposition, sputter deposition, physical vapor deposition, hot wire chemical vapor deposition, laser enhanced chemical vapor deposition, laser enhanced atomic layer deposition, rapid thermal chemical vapor deposition, spin on deposition, gas cluster ion beam deposition, or the like, utilized in fabrication of CEM devices from TMO materials. In expressions (6a) and (6b), “BY” may comprise an oxidizer, such as water (H₂O), oxygen (O₂), ozone (O₃), plasma O₂, hydrogen peroxide (H₂O₂). In other embodiments, “BY” may comprise CO, O₂+(CH₄), or nitric oxide (NO)+water (H₂O) or an oxynitride or carbon containing a gaseous oxidizing or oxynitridizing agent. In other embodiments, plasma may be used with an oxidizer (BY) to form oxygen radicals (O*). Likewise, plasma may be used with a dopant species to form an activated species to control dopant concentration in a CEM.

In particular embodiments, such as embodiments utilizing atomic layer deposition, a substrate, such as a conductive substrate, may be exposed to precursors, such as AX and BY, as well as dopants providing electron back-donation (such as ammonia or other ligands comprising metal-nitrogen bonds, including, for example, nickel-amides, nickel-imides, nickel-amidinates, or combinations thereof) in a heated chamber, which may attain, for example, a temperature approximately in the range of 20.0° C. to 1000.0° C., for example, or between temperatures approximately in the range of 20.0° C. and 500.0° C. in certain embodiments. In one particular embodiment, in which atomic layer deposition of NiO:NH₃, for example, is performed, chamber temperature ranges of about 20.0° C. to about 400.0° C. may be utilized. Responsive to exposure to precursor gases (e.g., AX, BY, NH₃, or other ligand comprising nitrogen), such gases may be purged from the heated chamber for durations in the range of about 0.5 seconds to about 180.0 seconds, for example. It should be noted, however, that these are merely examples of potentially suitable ranges of chamber temperature and/or time and claimed subject matter is not limited in this respect.

In certain embodiments, a single two-precursor cycle (e.g., AX and BY, as described with reference to expression 6(a)) or a single three-precursor cycle (e.g., AX, NH₃, CH₄, or other ligand comprising nitrogen, carbon, or other electron back-donating dopant derived from an extrinsic ligand and BY, as described with reference to expression 6(b)) utilizing atomic layer deposition may bring about a layer of a TMO material film comprising a thickness in the range of about 0.6 Å to about 5.0 Å per cycle). Accordingly, in one embodiment, if an atomic layer deposition process is capable of depositing layers of a TMO material film comprising a thickness of about 0.6 Å, 800-900 two-precursor cycles may be utilized to bring about a TMO material film comprising a thickness of about 500.0 Å. It should be noted that atomic layer deposition may be utilized to form TMO material films having other thicknesses, such as thicknesses in the range of about 1.5 nm to about 150.0 nm, for example, and claimed subject matter is not limited in this respect.

In particular embodiments, responsive to one or more two-precursor cycles (e.g., AX and BY), or three-precursor cycles (AX, NH₃, CH₄, or other ligand comprising nitrogen, carbon or other back-donating dopant material and BY), of atomic layer deposition, a TMO material film may be exposed to elevated temperatures, which may, at least in part, enable formation of a CEM device from a TMO material film. Exposure of the TMO material film to an elevated temperature may additionally enable activation of a back-donating dopant derived from an extrinsic ligand, such as in the form of carbon, carbonyl, or ammonia, responsive to repositioning of the dopant to metal oxide lattice structures of the CEM device film.

Thus, in this context, an “elevated temperature” means a temperature at which extrinsic or substitutional ligands evaporate from a TMO material film, and/or are repositioned within a TMO material film, to such an extent that the TMO material film transitions from a resistive film to a film that is capable of switching between a relatively high-impedance or insulative state to a relatively low-impedance or conductive state. For example, in certain embodiments, a TMO material film exposed to an elevated temperature within a chamber of about 100.0° C. to about 800.0° C. for a duration of about 30.0 seconds to about 120.0 minutes may permit evaporation of extrinsic ligands from the TMO material film so as to form a CEM film. Additionally, in certain embodiments, a TMO material film exposed to an elevated temperature within a chamber of about 100.0° C. to about 800.0° C. for a duration of about 30.0 seconds to about 120.0 minutes. may permit repositioning of extrinsic ligands, for example, at oxygen vacancies within a lattice structure of a metal oxide. In particular embodiments, elevated temperatures and exposure durations may comprise more narrow ranges, such as, for example, temperatures of about 200.0° C. to about 500.0° C. for about 1.0 minute to about 60.0 minutes, for example, and claimed subject matter is not limited in these respects.

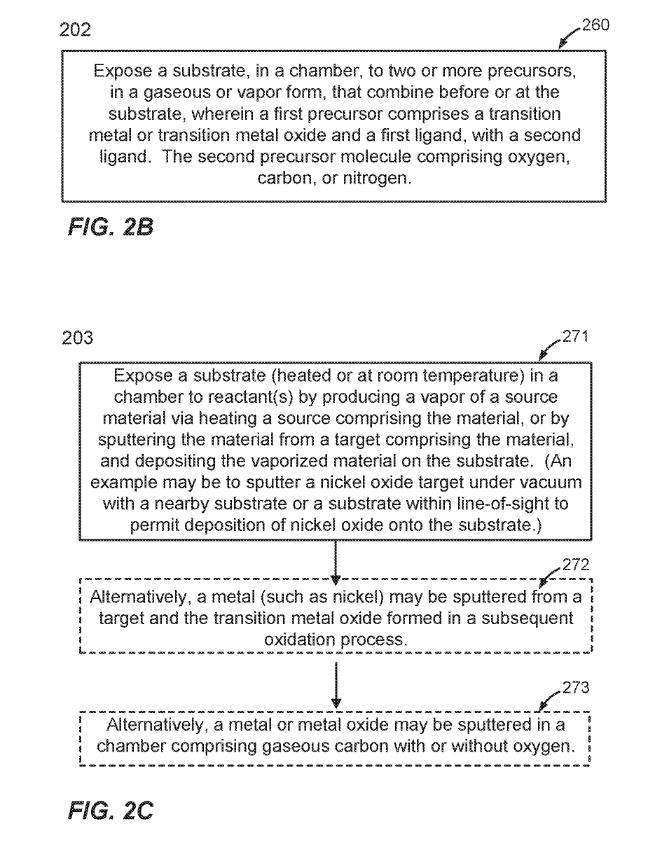

FIG. 2A shows a simplified flowchart for a method for fabricating correlated electron device materials according to an embodiment 201. Example implementations, such as described in FIGS. 2A, 2B, and 2C, for example, may include blocks in addition to those shown and described, fewer blocks, or blocks occurring in an order different than may be identified, or any combination thereof. In an embodiment, a method may include blocks 210, 230, and 250, for example. The method of FIG. 2A may accord with the general description of atomic layer deposition previously described herein. The method of FIG. 2A may begin at block 210, which may comprise exposing the substrate, in a heated chamber, for example, to a first precursor in a gaseous state (e.g., “AX”), wherein the first precursor comprises a transition metal oxide, a transition metal, a transition metal compound or any combination thereof, and a first ligand. The method may continue at block 220, which may comprise removing the precursor AX and byproducts of AX by using an inert gas or evacuation or combination. The method may continue at block 230, which may comprise exposing the substrate to a second precursor (e.g., BY) in a gaseous state, wherein the second precursor comprises a oxide so as to form a first layer of the film of a CEM device. The method may continue at block 240, which may comprise removing the precursor BY and byproducts of BY through the use of an inert gas or evacuation or combination. The method may continue at block 250, which may comprise repeating the exposing of the substrate to the first and second precursors with intermediate purge and/or evacuation steps so as to form additional layers of the film until the correlated electron material is capable of exhibiting a ratio of first to second impedance states of at least 5.0:1.0.

FIG. 2B shows a simplified flowchart for a method for fabricating correlated electron device materials according to an embodiment 202. The method of FIG. 2B may accord with the general description of chemical vapor deposition or CVD or variations of CVD such as plasma enhanced CVD and others. In FIG. 2B, such as at block 260, a substrate may be exposed to precursor AX and BY simultaneously under conditions of pressure and temperature to promote the formation of AB, which corresponds to a CEM. Additional approaches may be employed to bring about formation of a CEM, such as application of direct or remote plasma, use of hot wire to partially decompose precursors, or lasers to enhance reactions as examples of forms of CVD. The CVD film processes and/or variations, may for a duration and under conditions as can be determined by one skilled in the art of CVD until, for example, correlated electron material having appropriate thickness and exhibiting appropriate properties, such as electrical properties, such as a ratio of first to second impedance states of at least 5.0:1.0.

FIG. 2C shows a simplified flowchart for a method for fabricating correlated electron device materials according to an embodiment 203. The method of FIG. 2C may accord with the general description of physical vapor deposition or PVD or Sputter Vapor Deposition or variations of these and/or related methods. In FIG. 2C a substrate may be exposed in a chamber, for example, to an impinging stream of precursor having a “line of sight” under particular conditions of temperature and pressure to promote formation of a CEM comprising material AB. The source of the precursor may be, for example, AB or A and B from separate “targets” wherein deposition is brought about using a stream of atoms or molecules that are physically or thermally or by other means removed (sputtered) from a target comprised of material A or B or AB and are in “line of sight” of the substrate. In an implementation, a process chamber may be utilized wherein pressure within the process chamber pressure comprises a value low enough, such as a pressure value that approaches a lower threshold, or a pressure value lower than a threshold, such that the mean free path of the atoms or molecules or A or B or AB is approximately equal to or greater than the distance from the target to the substrate. The stream of AB (or A or B) or both may combine to form AB on the substrate due to conditions of the reaction chamber pressure, temperature of the substrate and other properties that are controlled by one skilled in the art of PVD and sputter deposition. In other embodiments of PVD or sputter deposition, the ambient environment may be a source such as BY or for example an ambient of O₂ for the reaction of sputtered nickel to form NiO doped with carbon or CO, for example co-sputtered carbon. The PVD film and its variations will continue for a time required and under conditions as can be determined by one skilled in the art of PVD until correlated electron material of thickness and properties is deposited that is capable of exhibiting a ratio of first to second impedance states of at least 5.0:1.0.

The method may continue at block 272 in which, at least some embodiments, a metal, such as nickel, may be sputtered from a target and a transition metal oxide may be formed in a subsequent oxidation process. The method may continue at block 273 in which, at least in some embodiments, a metal or metal oxide may be sputtered in a chamber comprising gaseous carbon with or without a substantial portion of oxygen.

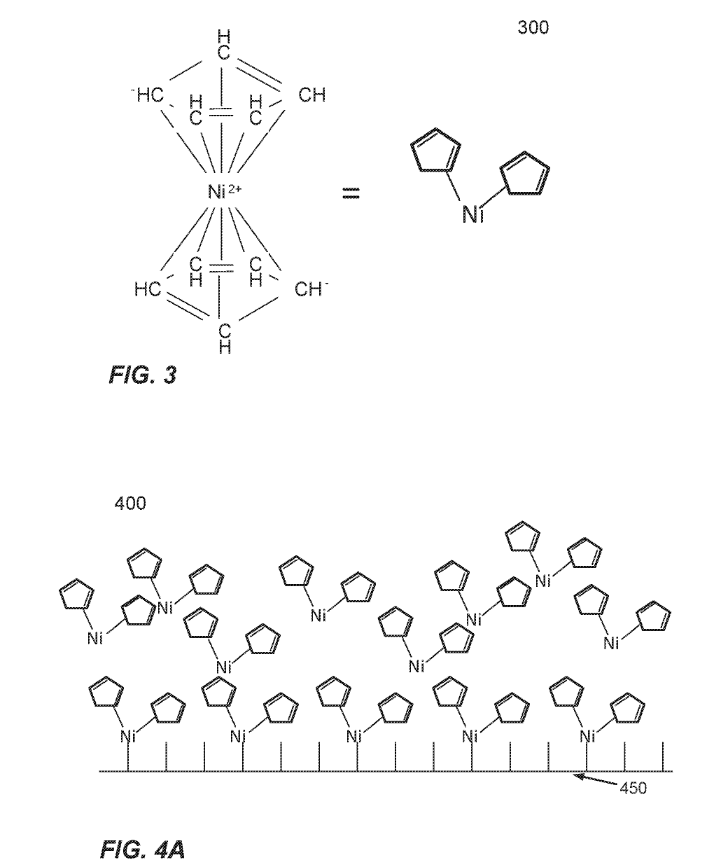

FIG. 3 is a diagram of a nickel dicyclopentadienyl molecule (Ni(C₅H₅)₂), which may be abbreviated as Ni(Cp)₂, may function as a precursor, in a gaseous form, utilized in fabrication of correlated electron materials according to an embodiment 300. As shown in FIG. 3, a nickel atom, near the center of the nickel dicyclopentadienyl molecule, has been placed in an ionization state of +2 to form an N²⁺ ion. In the example molecule of FIG. 3, an additional electron is present in the upper left and lower right CH⁻ sites of the cyclopentadienyl (Cp) portions of the dicyclopentadienyl ((Cp)₂) molecule. FIG. 3 additionally illustrates a shorthand notation showing nickel bonded to pentagon-shaped monomers of a dicyclopentadienyl molecule.

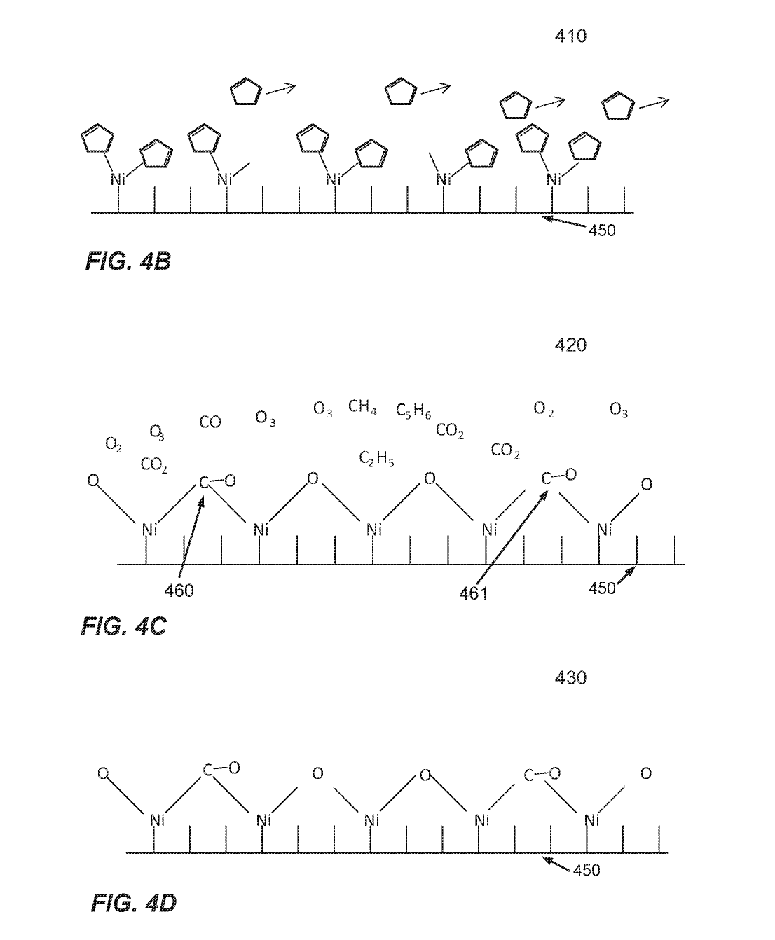

FIGS. 4A-4D show sub-processes utilized in a method for fabricating a film comprising a CEM according to an embodiment. The sub-processes of FIGS. 4A-4D may correspond to the atomic layer deposition process utilizing precursors AX and BY of expression (6) to deposit components of NiO:CO onto a conductive substrate. In embodiments, a conductive substrate may comprise an electrode material comprising titanium nitride, platinum, titanium, copper, aluminum, cobalt, nickel, tungsten, tungsten nitride, cobalt silicide, ruthenium oxide, chromium, gold, palladium, indium tin oxide, tantalum, silver, iridium, or any combination thereof. However, the sub-processes of FIGS. 4A-4D may be utilized, with appropriate material substitutions, to fabricate films comprising CEM that utilize other transition metals, transition metal oxides, transition metal compounds or combinations thereof, and claimed subject matter is not limited in this respect.

As shown in FIG. 4A, (embodiment 400) a substrate, such as substrate 450, may be exposed to a first gaseous precursor, such as precursor AX of expression (6), such as a gaseous precursor comprising nickel dicyclopentadienyl (Ni(Cp)₂) for a duration of in the range of about 0.5 seconds to about 180.0 seconds. As previously described, concentration, such as atomic concentration, of a first gaseous precursor, as well as exposure time, may be adjusted so as to bring about a final atomic concentration of carbon, such as in the form of carbonyl, of between about 0.1% and about 10.0%, for example. As shown in FIG. 4A, exposure of a substrate to gaseous (Ni(Cp)₂ may result in attachment of(Ni(Cp)₂) molecules or (Ni(Cp) at various locations of the surface of substrate 450. Deposition may take place in a heated chamber which may attain, for example, a temperature in the range of about 20.0° C. to about 400.0° C. However, it should be noted that additional temperature ranges, such as temperature ranges comprising less than about 20.0° C. and greater than about 400.0° C. are possible, and claimed subject matter is not limited in this respect.

As shown in FIG. 4B, (embodiment 410) after exposure of a conductive substrate, such as conductive substrate 450, to a gaseous precursor, such as a gaseous precursor comprising (Ni(Cp)₂), the chamber may be purged of remaining gaseous Ni(Cp)₂ and/or Cp ligands. In an embodiment, for the example of a gaseous precursor comprising (Ni(Cp)₂), the chamber may be purged for duration in the range of about 0.5 seconds to about 180.0 seconds. In one or more embodiments, a purge duration may depend, for example, on affinity (aside from chemical bonding) of unreacted ligands and byproducts with a transition metal, transition metal compounds, transition metal oxide, or the like surface as well as other surfaces present in the process chamber. Thus, for the example of FIG. 4B, if unreacted Ni(Cp)₂, Ni(Cp), Ni, and other byproducts were to exhibit an increased affinity for the surfaces of the substrate or chamber, a larger purge duration may be utilized to remove remaining gaseous ligands, such as those mentioned. In other embodiments, purge duration may depend, for example, on gas flow within the chamber. For example, gas flow within a chamber that is predominantly laminar may permit removal of remaining gaseous ligands at a faster rate, while gas flow within a chamber that is predominantly turbulent may permit removal of remaining ligands at a slower rate. It should be noted that claimed subject matter is intended to embrace purging of remaining gaseous material without regard to flow characteristics within a chamber.

As shown in FIG. 4C, (embodiment 420) a second gaseous precursor, such as precursor BY of expression (6), may be introduced into the chamber. As previously mentioned, a second gaseous precursor may comprise an oxidizer, which may operate to displace a first ligand, such as (Cp)₂, for example, and replace the ligand with an oxidizer, such as oxygen (O₂), ozone (O₃), nitric oxide (NO), hydrogen peroxide (H₂O₂), just to name a few examples. Accordingly, as shown in FIG. 4C, oxygen atoms may form bonds with at least some nickel atoms bonded to substrate 450. In an embodiment, precursor BY may oxidize (Ni(Cp)₂) to form a number of additional oxidizers, and/or combinations thereof, in accordance with expression (7) below:

Ni(C₅H₅)₂+O₃→NiO+potential byproducts (e.g., CO, CO₂, C₅H₅, C₅H₆, CH₃, CH₄, C₂H₅, C₂H₆, . . . ) (7)

Wherein C₅H₅ has been substituted for Cp in expression (7). As shown in FIG. 4C, a number of potential byproducts are shown, including C₂H₅, CO₂, CH₄, and C₅H₆. As is also shown in FIG. 4C, carbonyl (CO) molecules may bond to nickel oxide complexes, such as at sites 460 in 461, for example. In embodiments, such nickel-to-carbonyl bonds (e.g. NiO:CO), in an atomic concentration of between, for example, 0.1% and 10.0%, may bring about the substantially rapid conductor/insulator transition of a CEM device.

As shown in FIG. 4D, (embodiment 430) potential hydrocarbon byproducts, such as CO, CO₂, C₅H₅, C₅H₆, CH₃, CH₄, C₂H₅, C₂H₆, for example, may be purged from the chamber. In particular embodiments, such purging of the chamber may occur for a duration in the range of about 0.5 seconds to about 180.0 seconds utilizing a pressure in the range of about 0.01 Pa to about 105.0 kPa.

In particular embodiments, the sub-processes described shown in FIGS. 4A-4D may be repeated until a desired thickness, such as a thickness in the range of about 1.5 nm to about 100.0 nm, is achieved. As previously mentioned herein, atomic layer deposition approaches, such as shown and described with reference to FIGS. 4A-4D, for example, may give rise to a CEM device film having a thickness in the range of about 0.6 Å to about 1.5 Å for one ALD cycle, for example. Accordingly, to construct a CEM device film comprising a thickness of approximately 500.0 Å (50.0 nm), just as a possible example, approximately 300 to 900 two-precursor cycles, utilizing AX+BY for example, may be performed. In certain embodiments, cycles may be occasionally interspersed among differing transition metals, and/or transition metal compounds and/or transition metal oxides to obtain desired properties. For example, in an embodiment, two atomic layer deposition cycles, in which layers of NiO:CO may be formed, may be followed by three atomic layer deposition cycles to form, for example, titanium oxide carbonyl complexes (TiO:CO). Other interspersing of transition metals, and/or transition metal compounds and/or transition metal oxides is possible, and claimed subject matter is not limited in this respect.

In particular embodiments, after the completion of one or more atomic layer deposition cycles, a substrate may be annealed, which may assist in controlling grain structure, densifying the CEM film or otherwise improving the film properties, performance or endurance. For example, if atomic layer deposition produces the number of columnar shaped grains, annealing may permit boundaries of columnar-shaped grains to grow together which may, for example, reduce resistance variations of the CEM device, for example. In certain embodiments, annealing may operate to reduce concentration of a dopant present in a CEM film. For example, in one embodiment, a CEM film comprising an atomic concentration of between, for example, 5.0% and 25.0% carbon. Annealing may permit diffusion of a dopant, such as a carbon-containing dopant or a nitrogen-containing dopant, from a CEM film, which may reduce dopant atomic concentration of about 0.1% to about 15.0%, for example, Annealing may give rise to additional benefits, such as more evenly distributing of carbon molecules, such as carbonyl, for example, throughout the CEM device material, and claimed subject matter is not limited in this respect.

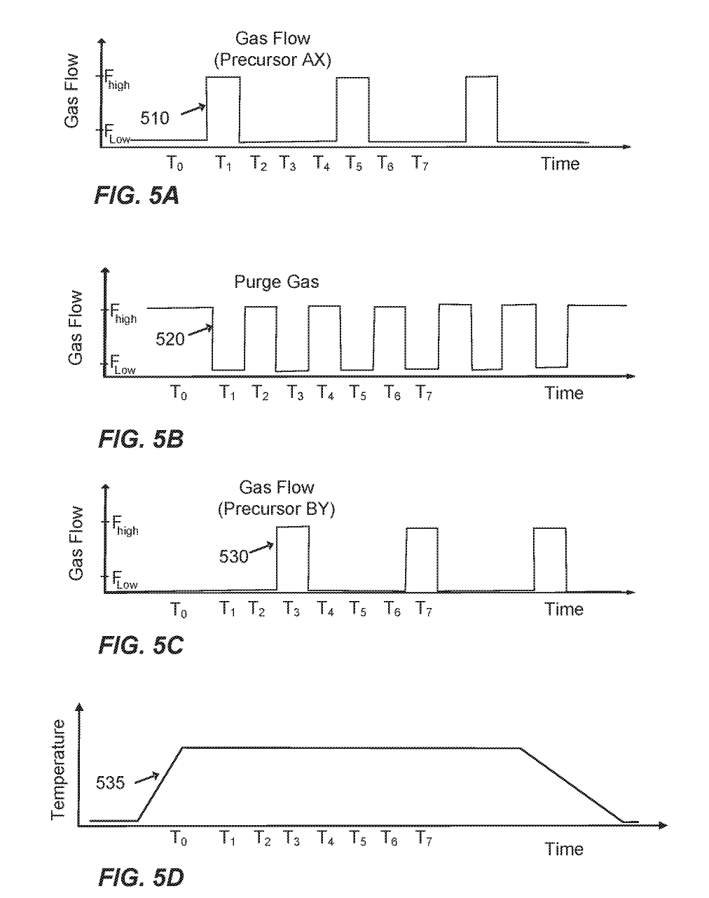

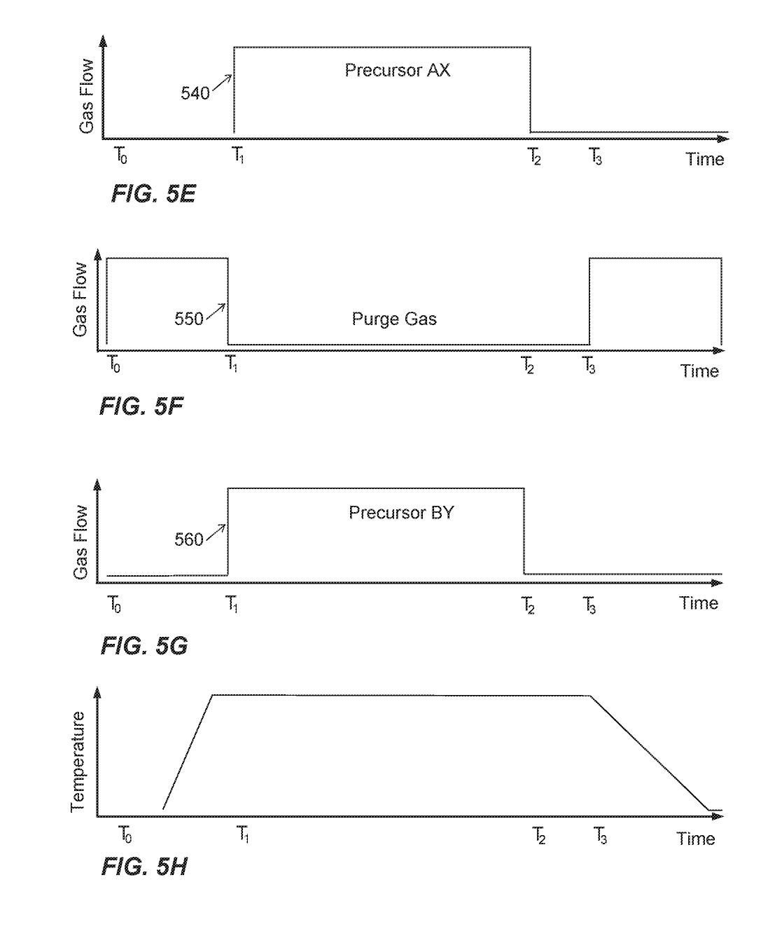

FIGS. 5A-5D are diagrams showing precursor flow and temperature profiles, as a function of time, which may be used in a method for fabricating correlated electron device materials according to an embodiment. A common timescale (T₀-T₇) is utilized for FIGS. 5A-5D. FIG. 5A shows a precursor flow profile 510 for a precursor (e.g., AX), according to an embodiment. As shown in FIG. 5B, precursor gas flow may be increased, so as to permit the precursor gas to enter a chamber within which a CEM device may be undergoing fabrication. Thus, in accordance with precursor gas flow profile 510, at time T₀, precursor AX gas flow may be approximately 0.0 (e.g., negligible). At time T₁, precursor AX gas flow may be increased to relatively higher value. At time T₂, which may correspond to a time in the range of about 0.5 seconds to about 180.0 seconds after time T₁, precursor AX gas may be purged and/or evacuated from the chamber, such as by purging, for example. Precursor AX gas flow may be stopped until approximately time T₅, at which time precursor AX gas flow may be increased to a relatively higher value. After time T₅, such as at times T₆ and T₇ precursor AX gas flow may be returned to 0.0 (e.g. negligible amount) until increased at a later time.

FIG. 5B shows a gas flow profile 520 for a purge gas, according to an embodiment. As shown in FIG. 5B, purge gas flow may be increased and decreased so as to permit evacuation of the fabrication chamber of precursor gases AX and BY, for example. At time T₀, purge gas profile 520 indicates a relatively high purge gas flow, which may permit removal of impurity gases within the fabrication chamber prior to time T₁. At time T₁, purge gas flow may be reduced to approximately 0.0, which may permit introduction of precursor AX gas into the fabrication chamber. At time T₂, purge gas flow may be increased for duration in the range of about 0.5 seconds to about 180.0 seconds so as to permit removal of excess precursor gas AY and reaction byproducts from the fabrication chamber.

FIG. 5C shows a gas flow profile 530 for a precursor gas (e.g., BY), according to an embodiment. As shown in FIG. 5C, precursor BY gas flow may remain at a flow of approximately 0.0 (e.g., negligible), until approximately time T₃, at which gas flow may be increased to relatively higher value. At time T₄, which may correspond to a time in the range of about 0.5 seconds to about 180.0 seconds after time T₂, precursor BY gas may be purged and/or evacuated from the chamber, such as by purging, for example. Precursor BY gas flow may be returned to 0.0, until approximately time T₇, at which time precursor BY gas flow may be increased to a relatively higher value.

At time T₃, purge gas flow may be decreased to a relatively low value, which may permit precursor BY gas to enter the fabrication chamber. After exposure of the substrate to precursor BY gas, purge gas flow may again be increased so as to permit removal of the fabrication chamber of precursor BY gas, which may signify completion of a single atomic layer of a CEM device film, for example. After removal of precursor BY gas, precursor AX gas may be reintroduced to the fabrication chamber so as to initiate a deposition cycle of a second atomic layer of a CEM device film. In particular embodiments, the above-described process of introduction of precursor AX gas into the fabrication chamber, purging of remaining precursor AX gas from the fabrication chamber, introduction of precursor BY gas, and purging of remaining precursor BY gas, may be repeated, for example, in the range of about 300 times to about 900 times, for example. Repetition of the above-described process may bring about CEM device films having a thickness dimension of, for example, between about 20.0 nm and about 100.0 nm, for example.

FIG. 5D is a diagram showing a temperature profile, as a function of time, used in a method for fabricating correlated electron device materials according to an embodiment. In FIG. 5D, a deposition temperature (shown by temperature profile 535) may be raised to attain a temperature of, for example, a value in the range of about 20.0° C. to about 900.0° C. However, in particular embodiments, somewhat smaller ranges may be utilized, such as temperature ranges in the range of about 100.0° C. to about 800.0° C. Further, for particular materials, even smaller temperature ranges may be utilized, such as from about 100.0° C. to about 600.0° C.

FIGS. 5E-5H are diagrams showing precursor flow and temperature profiles, as a function of time, which may be used in a method for fabricating correlated electron device materials according to an embodiment. A common timescale (T₀-T₃) is utilized for FIGS. 5E-5H. As shown in embodiment FIG. 5E, precursor AX (in accordance with gas flow profile 540) may be brought into a fabrication chamber at time T₁, where time T₀ to time T₁ represents a period during which the process chamber may be purged and/or evacuated in preparation for a deposition subprocess. As shown in FIG. 5F, an increase in purge gas flow such as shown by purge gas flow profile 550. Returning to FIG. 5E, a relative increase in the flow of precursor AX is shown as occurring at time T₁, which may coincide with a relative decrease in purge gas flow. In addition, at time T₁, flow of a second reactant precursor, BY, may be increased, as shown by gas flow profile 560 of FIG. 5G. The two precursors (AX and BY) may flow substantially at the same time for the amount of time required to bring about a desired thickness of the CEM film. The temperature profile shown in the embodiment of FIG. 5H indicates that the temperature for deposition is set before or near the time, T₀.

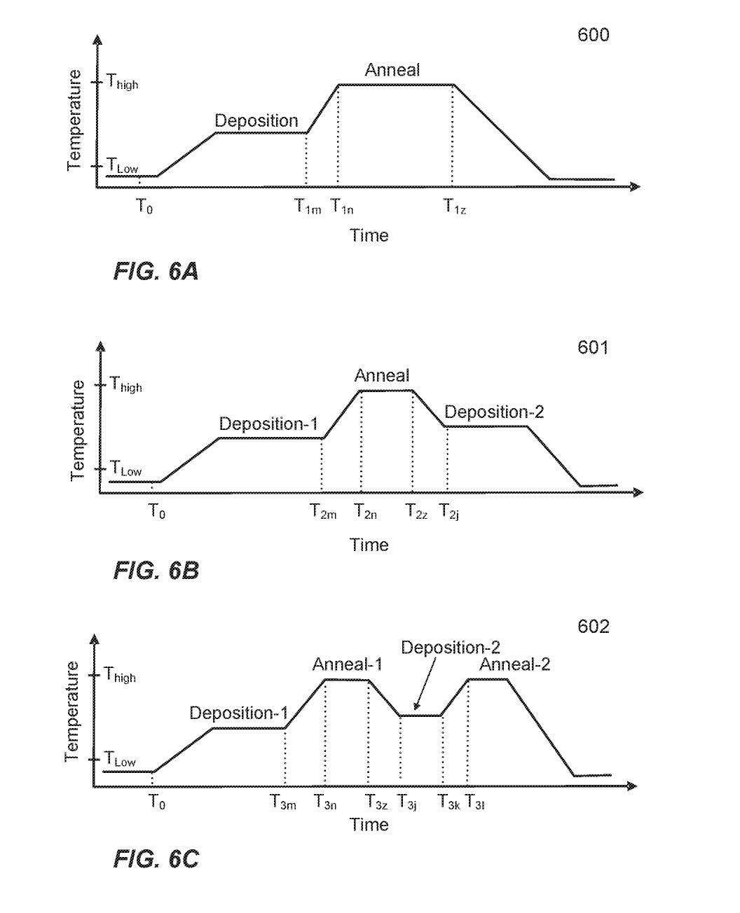

FIGS. 6A-6C are diagrams showing temperature profiles, as a function of time, used in deposition processes and annealing processes in connection with fabricating CEM devices according to an embodiment. As shown in FIG. 6A (embodiment 600), deposition may take place during an initial time span, such as from T₀ to T₁ₘ, during which time, a CEM device film may be deposited upon an appropriate substrate utilizing an atomic layer deposition process. After deposition of a CEM device film, an annealing period may follow. In some embodiments, a number of atomic layer deposition cycles may range from, for example, approximately 10 cycles, to as many as 1000 cycles or more, and claimed subject matter is not limited in this respect. After completion of deposition of a CEM film onto a suitable substrate, relatively high-temperature annealing or an annealing at the same temperature or lower temperature than the deposition temperature may be performed utilizing a temperature in the range of about 20.0° C. to about 900.0° C., such as from time T₁ₙ to time T_{1z}. However, in particular embodiments, smaller ranges may be utilized, such as temperature ranges in the range of about 100.0° C. to about 800.0° C. Further, for particular materials, even smaller temperature ranges may be utilized, such as from about 200.0° C. to about 600.0° C., for example, or from about 300.0° C. to about 400.0° C. In additional embodiments, a temperature range of, for example, between about 250.0° C. to about 500.0° C. may be utilized. Temperature ranges attained during an anneal process, such as 250.0° C., 300.0° C., 400.0° C., and 500.0° C. may be maintained for a duration of between about 10.0 minutes and 35.0 about minutes (e.g., about 20.0 minutes in one embodiment).

In particular embodiments, use of particular temperature ranges, such as temperature ranges not exceeding 400.0° C. or 500.0° C., for example, may permit annealing of a CEM film without giving rise to unwanted migration and/or diffusion of dopants present, for example, in underlying doped transistor materials. In addition, annealing temperatures of less than 400.0° C. or 500.0° C. may also be of benefit in the presence of, for example, dielectric materials having lower dielectric constants, which may comprise reduced thermal stability. Annealing times may range from about 1.0 second to about 5.0 hours, but may be narrowed to, for example, durations of about 0.2 minutes to about 180.0 minutes. It should be noted that claimed subject matter is not limited to any particular temperature ranges for annealing of CEM devices, nor is claimed subject matter limited to any particular durations of annealing. In other embodiments the deposition method may be chemical vapor deposition, physical vapor deposition, sputter, plasma enhanced chemical vapor deposition or other methods of deposition or combinations of deposition methods such as a combination of ALD and CVD in order to form the CEM film.

In embodiments, annealing may be performed in a gaseous environment comprising a substantial portion, which may comprise substantially or completely filling a chamber with one or more of gaseous nitrogen (N₂), hydrogen (H₂), oxygen (O₂), water or steam (H₂O), nitric oxide (NO), nitrous oxide (N₂O), nitrogen dioxide (NO₂), ozone (O₃), argon (Ar), helium (He), ammonia (NH₃), carbon monoxide (CO), carbon dioxide (CO₂), methane (CH₄), acetylene (C₂H₂), ethane (C₂H₆), propane (C₃H₈), ethylene (C₂H₄), butane (C₄H₁₀), or any combination thereof. Annealing may also occur in reduced-pressure environments, which may approach a vacuum, or pressures up to and in excess of a pressure of 1.0 atmosphere (which may defined as pressure of between about 100.0 kPa to about 105 kPa), including pressures of multiples of 1.0 atmosphere. In embodiments, a reduced-pressure environment within which annealing may be performed may comprise an ambient pressure of between about 1.0 kPa and about 80.0 kPa. In other embodiments, a reduced-pressure environment within which annealing may be performed may comprise an ambient pressure of between about 50.0 kPa and about 105.0 kPa. As shown in FIG. 6B (embodiment 601), deposition may take place during an initial time span, such as from T₀ to T₂ₘ, during which between about 10 and about 500 cycles of atomic layer deposition may be performed. At time T₂ₙ, an annealing period may be initiated and may continue until time T_{2z}. After time T_{2z}, a second set of atomic layer deposition cycles may occur, perhaps numbering between about 10 and about 500 cycles, for example. As shown in FIG. 6B, a second set of atomic layer deposition (Deposition-2) cycles may occur. In other embodiments the deposition method may be chemical vapor deposition, physical vapor deposition, sputter, plasma enhanced chemical vapor deposition or other methods of deposition or combinations of deposition methods such as a combination of ALD and CVD in order to form the CEM film.

As shown in FIG. 6C, (embodiment 602) deposition may take place during an initial time span, such as from time T₀ to time T₃m, during which between about 10 and about 500 cycles of atomic layer deposition may be performed. At time T₃ₙ, a first annealing period (Anneal-1) may be initiated and may continue until time T_{3z}. At time T₃ⱼ a second set of atomic layer deposition cycles (Deposition-2) may be performed until time T₃ₖ, at which a chamber temperature may be increased so that a second annealing period (Anneal-2) may occur, such as beginning at time T₃ₗ, for example. In other embodiments the deposition method may be chemical vapor deposition, physical vapor deposition, sputter, plasma enhanced chemical vapor deposition or other methods of deposition or combinations of deposition methods such as a combination of ALD and CVD in order to form the CEM film.

Annealing processes, such as those shown and described with reference to FIG. 6A-6C, for example, may be performed immediately following fabrication processes and without removing a CEM film from a fabrication chamber. For example, in particular embodiments, the “Endura” tool, available from the Applied Materials company, located at 3050 Bowers Avenue, Santa Clara, Calif., may be utilized to perform PVD. A feature of a fabrication tool, such as the Endura tool, may include an ability to perform annealing while a CEM film is situated within one of a plurality of process chambers. Accordingly, PVD and annealing processes may be performed without risk of exposing a CEM film to ambient atmosphere, which may give rise to unwanted and/or uncontrolled oxidation of the CEM film. An additional advantage of the Endura tool may relate to the tool comprising a reduced size compared to competing multi-chamber fabrication tools. In addition, the Endura tool, or similar tools, may permit multi-chamber fabrication of CEM devices in which all processes occur in a reduced-pressure environment, such as utilizing an ambient temperature of 0.1 kPa to 80.0 kPa.

In another embodiment, annealing processes, such as those shown and described with reference to FIG. 6A-6C, may be performed utilizing the “Gershwin” tool, also available from the Applied Materials company of Santa Clara, Calif. The Gershwin tool may, however, involve removal of a CEM film from a fabrication chamber prior to annealing in a gaseous environment, such as environment comprising gaseous nitrogen (N₂), hydrogen (H₂), oxygen (O₂), water or steam (H₂O), nitric oxide (NO), nitrous oxide (N₂O), nitrogen dioxide (NO₂), ozone (O₃), argon (Ar), helium (He), ammonia (NH₃), carbon monoxide (CO), carbon dioxide (CO₂), methane (CH₄), acetylene (C₂H₂), ethane (C₂H₆), propane (C₃H₈), ethylene (C₂H₄), butane (C₄H₁₀), or any combination thereof. An advantage of removal of a CEM film prior to annealing in a gaseous environment may relate to a desire to avoid or to at least reduce exposure of a fabrication chamber to potentially caustic gaseous components which may potentially damage structures and/or equipment within the one or more chambers of a fabrication tool.

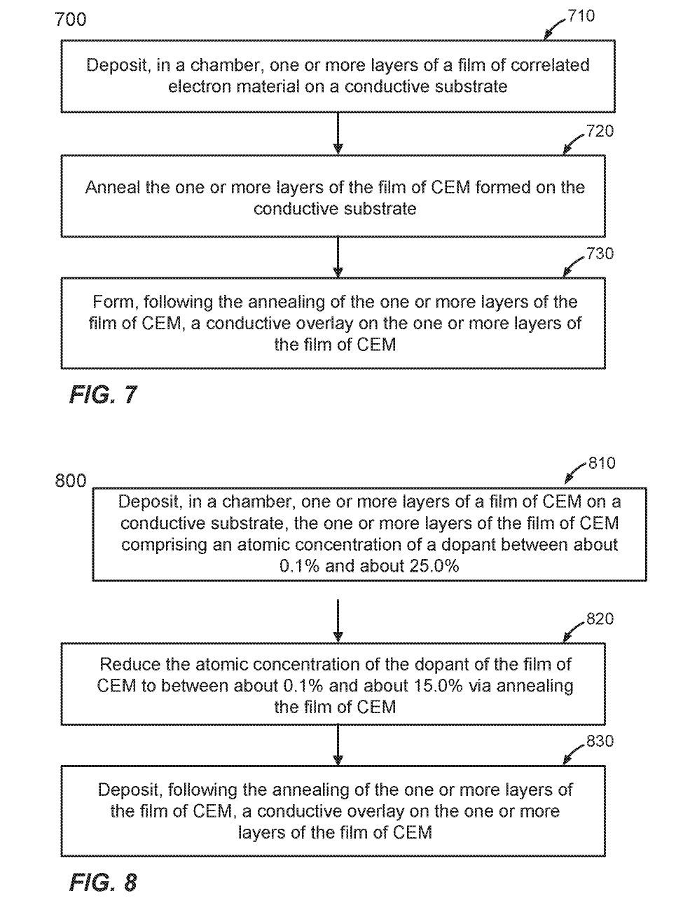

FIGS. 7 and 8 are flowcharts for additional methods of fabricating correlated electron material films according to one or more embodiments. The method of FIG. 7 (embodiment 700) may begin at block 710, which may comprise depositing, any chamber, one or more layers of a film of correlated electron material on a conductive substrate. Block 720 may comprise annealing the one or more layers of the film of CEM formed on the conductive substrate. At block 730, following the annealing of the one or more layers of the film of CEM, a conductive overlay may be formed on the one or more layers of the film of CEM.

The method of FIG. 8 (embodiment 800) may begin at block 810, which may comprise depositing, any chamber, one or more layers of a film of CEM on a conductive substrate, wherein the one or more layers of the film of CM comprise an atomic concentration of a dopant between about 0.1% and about 25.0%. Block 820 may comprise reducing the atomic concentration of the dopant of the CEM film to between about 0.1% and about 15.0% via annealing the film of CEM. The method may continue at block 830, which may comprise depositing, following the annealing of the one or more layers of the film of CEM, a conductive overlay on the one or more layers of the film of CEM.

In embodiments, CEM devices may be implemented in any of a wide range of integrated circuit types. For example, numerous CEM devices may be implemented in an integrated circuit to form a programmable memory array, for example, that may be reconfigured by changing impedance states for one or more CEM devices, in an embodiment. In another embodiment, programmable CEM devices may be utilized as a non-volatile memory array, for example. Of course, claimed subject matter is not limited in scope to the specific examples provided herein.

A plurality of CEM devices may be formed to enable integrated circuit devices, which may include, for example, a first correlated electron device having a first correlated electron material and a second correlated electron device having a second correlated electron material, wherein the first and second correlated electron materials may comprise substantially dissimilar impedance characteristics that differ from one another. In addition, in an embodiment, a first CEM device and a second CEM device, comprising impedance characteristics that differ from one another, may be formed within a particular level of an integrated circuit. Further, in an embodiment, forming the first and second CEM devices within a particular level of an integrated circuit may include forming the CEM devices at least in part by selective epitaxial deposition. In another embodiment, the first and second CEM devices within a particular level of the integrated circuit may be formed at least in part by ion implantation, such as to alter impedance characteristics for the first and/or second CEM devices, for example.

In the preceding description, in a particular context of usage, such as a situation in which tangible components (and/or similarly, tangible materials) are being discussed, a distinction exists between being “on” and being “over.” As an example, deposition of a substance “on” a substrate refers to a deposition involving direct physical and tangible contact without an intermediary, such as an intermediary substance (e.g., an intermediary substance formed during an intervening process operation), between the substance deposited and the substrate in this latter example; nonetheless, deposition “over” a substrate, while understood to potentially include deposition “on” a substrate (since being “on” may also accurately be described as being “over”), is understood to include a situation in which one or more intermediaries, such as one or more intermediary substances, are present between the substance deposited and the substrate so that the substance deposited is not necessarily in direct physical and tangible contact with the substrate.

A similar distinction is made in an appropriate particular context of usage, such as in which tangible materials and/or tangible components are discussed, between being “beneath” and being “under.” While “beneath,” in such a particular context of usage, is intended to necessarily imply physical and tangible contact (similar to “on,” as just described), “under” potentially includes a situation in which there is direct physical and tangible contact, but does not necessarily imply direct physical and tangible contact, such as if one or more intermediaries, such as one or more intermediary substances, are present. Thus, “on” is understood to mean “immediately over” and “beneath” is understood to mean “immediately under.”

It is likewise appreciated that terms such as “over” and “under” are understood in a similar manner as the terms “up,” “down,” “top,” “bottom,” and so on, previously mentioned. These terms may be used to facilitate discussion, but are not intended to necessarily restrict scope of claimed subject matter. For example, the term “over,” as an example, is not meant to suggest that claim scope is limited to only situations in which an embodiment is right side up, such as in comparison with the embodiment being upside down, for example. An example includes a flip chip, as one illustration, in which, for example, orientation at various times (e.g., during fabrication) may not necessarily correspond to orientation of a final product. Thus, if an object, as an example, is within applicable claim scope in a particular orientation, such as upside down, as one example, likewise, it is intended that the latter also be interpreted to be included within applicable claim scope in another orientation, such as right side up, again, as an example, and vice-versa, even if applicable literal claim language has the potential to be interpreted otherwise. Of course, again, as always has been the case in the specification of a patent application, particular context of description and/or usage provides helpful guidance regarding reasonable inferences to be drawn.

Unless otherwise indicated, in the context of the present disclosure, the term “or” if used to associate a list, such as A, B, or C, is intended to mean A, B, and C, here used in the inclusive sense, as well as A, B, or C, here used in the exclusive sense. With this understanding, “and” is used in the inclusive sense and intended to mean A, B, and C; whereas “and/or” can be used in an abundance of caution to make clear that all of the foregoing meanings are intended, although such usage is not required. In addition, the term “one or more” and/or similar terms is used to describe any feature, structure, characteristic, and/or the like in the singular, “and/or” is also used to describe a plurality and/or some other combination of features, structures, characteristics, and/or the like. Furthermore, the terms “first,” “second,” “third,” and the like are used to distinguish different aspects, such as different components, as one example, rather than supplying a numerical limit or suggesting a particular order, unless expressly indicated otherwise. Likewise, the term “based on” and/or similar terms are understood as not necessarily intending to convey an exhaustive list of factors, but to allow for existence of additional factors not necessarily expressly described.

Furthermore, it is intended, for a situation that relates to implementation of claimed subject matter and is subject to testing, measurement, and/or specification regarding degree, to be understood in the following manner. As an example, in a given situation, assume a value of a physical property is to be measured. If alternatively reasonable approaches to testing, measurement, and/or specification regarding degree, at least with respect to the property, continuing with the example, is reasonably likely to occur to one of ordinary skill, at least for implementation purposes, claimed subject matter is intended to cover those alternatively reasonable approaches unless otherwise expressly indicated. As an example, if a plot of measurements over a region is produced and implementation of claimed subject matter refers to employing a measurement of slope over the region, but a variety of reasonable and alternative techniques to estimate the slope over that region exist, claimed subject matter is intended to cover those reasonable alternative techniques, even if those reasonable alternative techniques do not provide identical values, identical measurements or identical results, unless otherwise expressly indicated.

It is further noted that the terms “type” and/or “like,” if used, such as with a feature, structure, characteristic, and/or the like, using “optical” or “electrical” as simple examples, means at least partially of and/or relating to the feature, structure, characteristic, and/or the like in such a way that presence of minor variations, even variations that might otherwise not be considered fully consistent with the feature, structure, characteristic, and/or the like, do not in general prevent the feature, structure, characteristic, and/or the like from being of a “type” and/or being “like,” (such as being an “optical-type” or being “optical-like,” for example) if the minor variations are sufficiently minor so that the feature, structure, characteristic, and/or the like would still be considered to be predominantly present with such variations also present. Thus, continuing with this example, the terms optical-type and/or optical-like properties are necessarily intended to include optical properties. Likewise, the terms electrical-type and/or electrical-like properties, as another example, are necessarily intended to include electrical properties. It should be noted that the specification of the present disclosure merely provides one or more illustrative examples and claimed subject matter is intended to not be limited to one or more illustrative examples; however, again, as has always been the case with respect to the specification of a patent application, particular context of description and/or usage provides helpful guidance regarding reasonable inferences to be drawn.

In the preceding description, various aspects of claimed subject matter have been described. For purposes of explanation, specifics, such as amounts, systems, and/or configurations, as examples, were set forth. In other instances, well-known features were omitted and/or simplified so as not to obscure claimed subject matter. While certain features have been illustrated and/or described herein, many modifications, substitutions, changes, and/or equivalents will occur to those skilled in the art. It is, therefore, to be understood that the appended claims are intended to cover all modifications and/or changes as fall within claimed subject matter.

What is claimed is:

1. A method comprising:
depositing, in a chamber, one or more layers of a film of correlated electron material (CEM) on a conductive substrate;
annealing the one or more layers of the film of CEM formed on the conductive substrate; and
forming, following the annealing of the one or more layers of the film of CEM, a conductive overlay on the one or more layers of the film of CEM.

2. The method of claim 1, wherein depositing comprises utilizing a chemical vapor deposition process or utilizing a physical vapor deposition process.

3. The method of claim 1, wherein annealing the one or more layers of the film of CEM comprises exposing the film to a temperature of between about 300.0° C. and about 400.0° C. for a duration of about 20.0 min.

4. The method of claim 3, wherein annealing the one or more layers of the film of CEM comprises exposing the one or more layers of the film of CEM to a pressure comprising a value of between 1.0 kPa and 80.0 kPa.

5. The method of claim 3, wherein annealing the one or more layers of the film is performed via exposure of the one or more layers of the film of CEM to a pressure of between about 50.0 kPa to about 105.0 kPa.

6. The method of claim 3, further comprising removing the film of CEM from the chamber prior to annealing.

7. The method of claim 3, wherein the annealing is performed in the chamber, the chamber being substantially filled with gaseous oxygen.

8. The method of claim 3, wherein the annealing is performed in the chamber, the chamber being substantially filled with gaseous nitrogen.

9. The method of claim 1, wherein depositing one or more layers of a film of CEM on the conductive substrate gives rise to an atomic concentration of a dopant within the film of CEM of between 0.1% and 25.0%.

10. The method of claim 9, wherein the dopant comprises a carbon-containing dopant.

11. The method of claim 9, wherein annealing the one or more layers of the film of CEM comprises reducing the atomic concentration of the dopant within the film of CEM to between about 0.1% and about 15.0%.

12. A method comprising:
depositing, in a chamber, one or more layers of a film of correlated electron material (CEM) on a conductive substrate, the one or more layers of the film of CEM comprising an atomic concentration of a dopant of between about 0.1% and about 25.0%;
reducing the atomic concentration of the dopant of the film of CEM to between about 0.1% and about 15.0% via annealing the film of CEM; and
depositing, following the annealing of the one or more layers of the film of CEM, a conductive overlay on the one or more layers of the film of CEM.

13. The method of claim 12, wherein depositing comprises utilizing a chemical vapor deposition process or a physical vapor deposition process.

14. The method of claim 12, wherein annealing the one or more layers of the film of CEM comprises exposing the film to a temperature of between about 250.0° C. and about 500.0° C. for a duration of about 10.0 minutes to about 35.0 minutes.

15. The method of claim 14, wherein annealing the one or more layers of the film of CEM comprises exposing the one or more layers of the film of CEM to a pressure comprising a value of between 1.0 kPa and 80.0 kPa.

16. The method of claim 14, further comprising removing the film of CEM from the chamber prior to annealing.

17. The method of claim 14, wherein the annealing is performed in an environment substantially filled with gaseous oxygen.

18. The method of claim 14, wherein the annealing is performed in an environment substantially filled with gaseous nitrogen.

19. The method of claim 12, wherein the dopant comprises a carbon-containing dopant.

20. The method of claim 19, wherein the carbon-containing dopant comprises carbonyl.

21. The method of claim 12, further comprising forming the conductive substrate from a material comprising titanium nitride, platinum, titanium, copper, aluminum, cobalt, nickel, tungsten, tungsten nitride, cobalt silicide, ruthenium oxide, chromium, gold, palladium, indium tin oxide, tantalum, silver or iridium, or any combination thereof.
